(19) United States
(12) Patent Application Publication
(10) Pub. No.: US 2026/0271221 A1
(43) Pub. Date: Sep. 10, 2026

(54) HOT-SWAPPABLE COMPUTER FAN

(71) Applicant: Aivres Systems Inc., San Jose, CA (US)

(72) Inventor: Zhwei ZHANG, New Taipei City (TW)

(21) Appl. No.: 19/071,643

(22) Filed: Mar. 5, 2025

(51) Int. Cl. H05K 7/20; G06F 1/20; H10D 80/20

(52) U.S. Cl. CPC H05K 7/20172; G06F 1/20; H10D 80/213; H10D 80/215; H10D 80/251

(57) ABSTRACT

Disclosed herein are computer fan systems, computer systems, devices, and methods related to a hot-swappable computer fan. A computer fan system disclosed herein includes a computer fan, an N-type Metal-Oxide Semiconductor (NMOS) transistor, a first, second, and third resistor, a capacitor, and a first and a second P-type Metal-Oxide Semiconductor (PMOS) transistor. A method disclosed herein of connecting a device to a computer system includes connecting a ground terminal of the device and an electrical ground of the computer system, and after a delay in time, connecting any signal or power terminal of the device to the computer system. The method can include charging a capacitor until a voltage across the capacitor is sufficient to trigger an NMOS transistor.

### TECHNICAL FIELD

This disclosure is generally related to a hot-swappable fan for use in computer systems.

### BACKGROUND

Computer fans have not always been hot-swappable. Before hot-swappable fans, whenever a computer fan needs maintenance, it used to be the case that the system must be powered off, which resulted in down time and loss of productivity.

Hot-swappable computer fans allow technicians to replace the computer fans installed on a computer while the computer is running. However, the “ground bounce” phenomenon can sometimes occur the instant a computer fan is connected to a computer system when it is powered on, which can damage the fan or the computer system. Here “ground bounce” refers to the temporary voltage fluctuation that occurs between the local ground potential near the fan and the overall system ground, caused by the ground level at the fan being momentarily different from the true ground level on the motherboard when they are fist connected. This voltage fluctuation can affect the signal integrity of nearby circuits, potentially causing logic errors if the voltage shift is large enough that a low signal may be misinterpret as a high signal.

“Ground bounce” can be avoided by a power-on delay. Specifically, the ground of the fan and the ground of the computer motherboard are first connected, which ensures that there is no voltage difference between the two, and only then are the signal and power wires of the fan connected to the computer. Therefore, there is no voltage difference between the ground levels the instant when the fan is connected to the computer.

Disclosed herein is circuitry that implements the power-on delay in order to avoid “ground bounce” when installing hot-swappable computer fans or any other hardware components.

### SUMMARY

Described herein is a hot-swappable fan for use in computer systems.

In one general aspect, disclosed herein is a computer fan system comprising a computer fan comprising a ground terminal and a power terminal, an N-type Metal-Oxide Semiconductor (NMOS) transistor comprising a source terminal connected to ground, a first resistor connected between a positive voltage supply and a gate terminal of the NMOS transistor, a second resistor connected between the gate terminal of the NMOS transistor and the ground, a third resistor connected between the positive voltage supply and a drain terminal of the NMOS transistor, a capacitor connected between the gate terminal of the NMOS transistor and the ground, and a first and a second P-type Metal-Oxide Semiconductor (PMOS) transistor. In some embodiments, the ground terminal of the computer fan is connected to the ground. In some embodiments, the power terminal of the computer fan is connected to a source terminal of the first PMOS transistor. In some embodiments, a drain terminal of the first PMOS transistor is connected to a drain terminal of the second PMOS transistor. In some embodiments, gate terminals of the first and the second PMOS transistors are both connected to the drain terminal of the NMOS transistor. In some embodiments, a source terminal of the second PMOS transistor is connected to the positive voltage supply.

In some embodiments of the computer fan system, the positive voltage supply is a +12V DC voltage supply.

In some embodiments of the computer fan system, the computer fan further comprises a tachometer terminal. In addition, the computer fan system further comprises a third and a fourth PMOS transistor; the tachometer terminal of the computer fan is connected to a source terminal of the third PMOS transistor; a drain terminal of the third PMOS transistor is connected to a drain terminal of the fourth PMOS transistor; and gate terminals of the third and the fourth PMOS transistors are both connected to the drain terminal of the NMOS transistor.

In some embodiments of the computer fan system, the computer fan further comprises a Pulse-Width Modulation (PWM) terminal. In addition, the computer fan system further comprises a fifth and a sixth PMOS transistor; the PWM terminal of the computer fan is connected to a source terminal of the fifth PMOS transistor; a drain terminal of the fifth PMOS transistor is connected to a drain terminal of the sixth PMOS transistor; and gate terminals of the fifth and the sixth PMOS transistors are both connected to the drain terminal of the NMOS transistor.

In some embodiments of the computer fan system, the computer fan further comprises a second tachometer terminal. In addition, the computer fan system further comprises a seventh and an eighth PMOS transistor; the second tachometer terminal of the computer fan is connected to a source terminal of the seventh PMOS transistor; a drain terminal of the seventh PMOS transistor is connected to a drain terminal of the eighth PMOS transistor; and gate terminals of the seventh and the eighth PMOS transistors are both connected to the drain terminal of the NMOS transistor.

In another general aspect, disclosed herein is a computer system comprising a computer fan system as described above, and the computer fan system is releasably attached to the motherboard via a fan plug and a fan connector.

In some embodiments of the computer system, the computer fan system and the motherboard are connected via the ground and the positive voltage supply.

In some embodiments of the computer system, the computer fan system and the motherboard are connected via the ground, the positive voltage supply, and the drain terminal of the fourth PMOS transistor.

In some embodiments of the computer system, the computer fan system and the motherboard are connected via the ground, and the positive voltage supply, the drain terminal of the fourth PMOS transistor, and the drain terminal of the sixth PMOS transistor.

In some embodiments of the computer system, the computer fan system and the motherboard are connected via the ground, the positive voltage supply, the drain terminal of the fourth PMOS transistor, the drain terminal of the sixth PMOS transistor, and the drain terminal of the eighth PMOS transistor.

In yet another general aspect, disclosed herein is device comprising a hardware component comprising a ground terminal and a first power or signal terminal, an NMOS transistor comprising a source terminal connected to a ground, a first resistor connected between a positive voltage supply and a gate terminal of the NMOS transistor, a second resistor connected between the gate terminal of the NMOS transistor and the ground, a third resistor connected between the positive voltage supply and a drain terminal of the NMOS transistor, a capacitor connected between the gate terminal of the NMOS transistor and the ground, a first and a second PMOS transistor. In some embodiments, the ground terminal of the hardware component is connected to the ground. In some embodiments, the first power or signal terminal of the hardware component is connected to a source terminal of the first PMOS transistor. In some embodiments, drain terminals of the first and the second PMOS transistors are connected together. In some embodiments, gate terminals of the first and the second PMOS transistors are both connected to the drain terminal of the NMOS transistor.

In some embodiments of the device, the hardware component is a hot-swappable computer hardware component.

In some embodiments of the device, the hardware component is a computer fan.

In yet another general aspect, disclosed herein is a method of connecting a device to a computer system, comprising connecting a ground terminal of the device and an electrical ground of the computer system, and after a delay in time, connecting any signal or power terminal of the device to the computer system.

In some embodiments of the method, the delay in time is between about 10 milliseconds and about 50 milliseconds.

In some embodiment of the method, the device is a computer fan. In some embodiments, connecting any signal or power terminal of the device to the computer system comprises connecting a power terminal, tachometer terminal, and a PWM terminal of the fan to the computer system.

In some embodiment of the method, the method further comprises attaching a plug of the device to a corresponding connector of the computer system. In some embodiments, the computer system is powered on when attaching the plug of the device to the corresponding connector of the computer system. In some embodiments, the device is a computer fan, and the corresponding connector is a fan connector on a motherboard of the computer system.

In some embodiments of the method, connecting any signal or power terminal of the device to the computer system after the delay in time comprises charging a capacitor until a voltage across the capacitor is sufficient to trigger an NMOS transistor.

### BRIEF DESCRIPTION OF THE DRAWINGS

Certain features of various embodiments of the present technology are set forth with particularity in the appended claims. A better understanding of the features and advantages of the technology will be obtained by reference to the following detailed description that sets forth illustrative embodiments, in which the principles of the disclosure are utilized, and the accompanying drawings of which:

FIG. 1 illustrates a computer with circuitry for a power-on delay.

FIGS. 2A, 2B, and 2C illustrate a female connector.

FIGS. 3A and 3B illustrate a male connector.

FIG. 4 illustrates the steps in a method of connecting a fan to a computer system.

### DETAILED DESCRIPTION OF EMBODIMENTS

In the following description, certain specific details are set forth in order to provide a thorough understanding of various embodiments of the disclosure. However, one skilled in the art will understand that the disclosure may be practiced without these details. Moreover, while various embodiments of the disclosure are disclosed herein, many adaptations and modifications may be made within the scope of the disclosure in accordance with the common general knowledge of those skilled in this art. Such modifications include the substitution of known equivalents for any aspect of the disclosure in order to achieve the same result in substantially the same way.

Unless the context requires otherwise, throughout the present specification and claims, the word “comprise” and variations thereof, such as, “comprises” and “comprising” are to be construed in an open, inclusive sense, that is as “including, but not limited to.” Recitation of numeric ranges of values throughout the specification is intended to serve as a shorthand notation of referring individually to each separate value falling within the range inclusive of the values defining the range, and each separate value is incorporated in the specification as it were individually recited herein. Additionally, the singular forms “a,” “an” and “the” include plural referents unless the context clearly dictates otherwise.

Reference throughout this specification to “one embodiment” or “an embodiment” means that a particular feature, structure, or characteristic described in connection with the embodiment is included in at least one embodiment of the present disclosure. Thus, the appearances of the phrases “in one embodiment” or “in an embodiment” in various places throughout this specification are not necessarily all referring to the same embodiment, but may be in some instances. Furthermore, the particular features, structures, or characteristics may be combined in any suitable manner in one or more embodiments.

The term “about” is used herein to mean approximately, in the region of, roughly, or around. When the term “about” is used in conjunction with a numerical range, it modifies that range by extending the boundaries above and below the numerical values set forth. In general, the term “about” or “approximately” is used herein to modify a numerical value above and below the stated value by a variance of 20%.

The embodiments will now be explained with the accompanying figures.

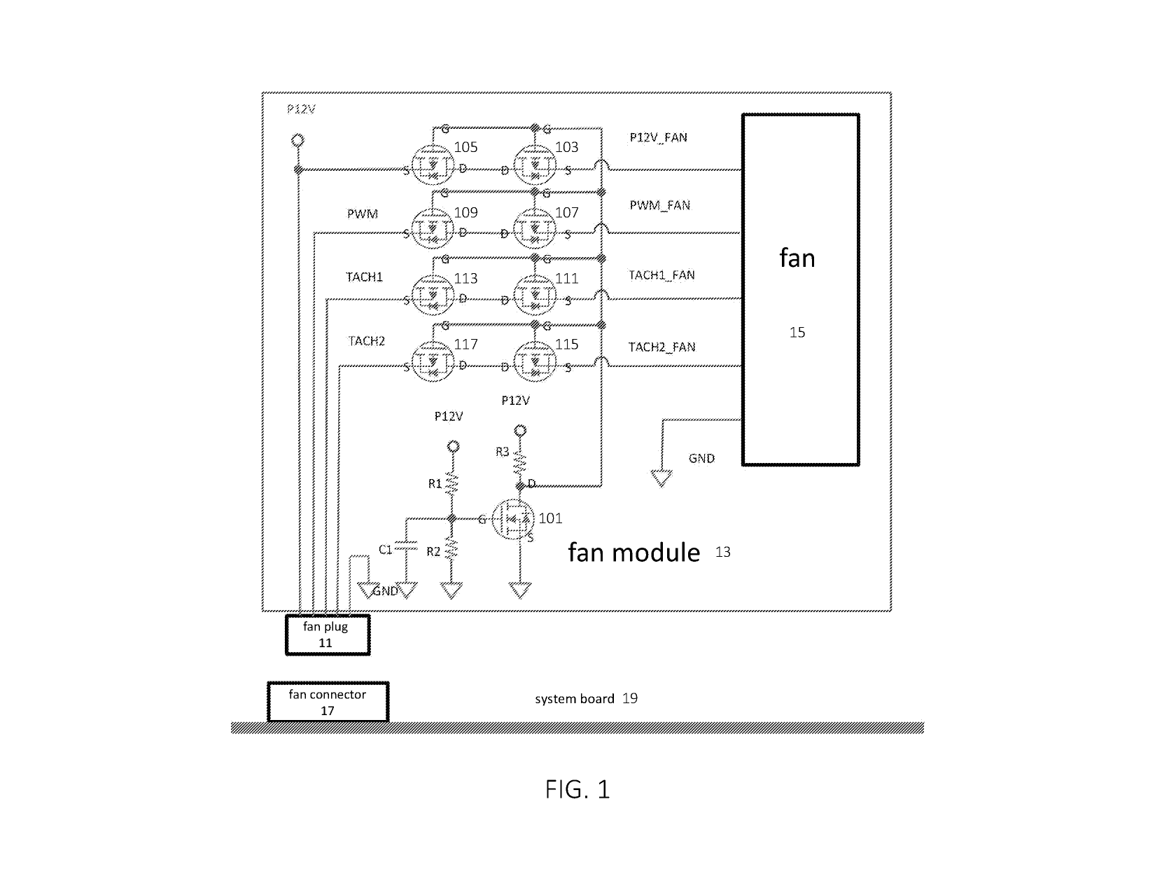

FIG. 1 illustrates a system board 19 (i.e., motherboard) of a computer system, on which a fan connector 17 is mounted. FIG. 1 also illustrates a fan module 13 containing a fan plug 11. The fan plug 11 and the fan connector 17 can be engaged, thereby connecting the fan module 13 to the system board 19.

The fan module 13 contains a computer fan 15. The computer fan 15 has five terminals for +12V DC power (P12V_FAN), ground (GND), tachometer 1 (TACH1_FAN), tachometer 2 (TACH1_FAN), and PWM (PWM_FAN), respectively. In some other embodiments, the computer fan is an off-the-shelf commercially available fan with a 2-pin, 3-pin, or 4-pin connection. In some embodiments, the computer fan has two terminals for +12V DC power and ground, respectively. In some embodiments, the computer fan has three terminals for +12V DC power, ground, and tachometer, respectively. In some embodiments, the computer fan has four terminals for +12V DC power, ground, tachometer, and PWM, respectively.

The circuitry in the fan module 13 includes an NMOS transistor 101 with a source terminal S connected to ground, a first resistor R1 connected between a +12V supply P12V and a gate terminal G of the NMOS transistor 101, a second resistor R2 connected between the gate terminal G of the NMOS transistor and the ground, a third resistor R3 connected between the +12V voltage supply P12V and a drain terminal D of the NMOS transistor, a capacitor C connected between the gate terminal G of the NMOS transistor and the ground, and a first PMOS transistor 103 and a second PMOS transistor 105. The ground terminal GND of the computer fan 15 is connected to the ground. The power terminal P12V_FAN of the computer fan 15 is connected to a source terminal S of the first PMOS transistor 103. A drain terminal D of the first PMOS transistor 103 is connected to a drain terminal D of the second PMOS transistor 105. Gate terminals G of the first and the second PMOS transistors 103 and 105 are both connected to the drain terminal D of the NMOS transistor 101. A source terminal S of the second PMOS transistor 105 is connected to the power supply pin P12V in the fan plug 11.

In operation, as soon as the fan plug 11 and the fan connector 17 are engaged, the 12V power supply P12V starts to charge the capacitor C1, until the voltage across C1 is sufficient to trigger the NMOS transistor 101 and switching it on. The duration of this process is the power-on delay. The duration of the delay is predetermined by choosing the capacitance of capacitor C1, the resistances of the first and the second resistors R1 and R2, and by selecting the NMOS. In some embodiments, the duration of the delay is selected based on the current requirement of the fan 15.

In some embodiments, such as the embodiment shown in FIG. 1, the computer fan 15 further includes a tachometer terminal TACH1_FAN, and the computer fan module 13 further includes a third and a fourth PMOS transistor 111 and 113. The tachometer terminal TACH1_FAN of the computer fan 15 is connected to a source terminal S of the third PMOS transistor 111. A drain terminal D of the third PMOS transistor 111 is connected to a drain terminal D of the fourth PMOS transistor 113. Gate terminals G of the third and the fourth PMOS transistors 111 and 113 are both connected to the drain terminal D of the NMOS transistor 101. A source terminal S of the fourth PMOS transistor 113 is connected to the tachometer pin TACH1 in the fan plug 11.

In some embodiments, such as the embodiment shown in FIG. 1, the computer fan 15 further includes a PWM terminal PWM_FAN, and the computer fan module 13 further includes a fifth and a sixth PMOS transistor 107 and 109. The PWM terminal PWM_FAN of the computer fan 15 is connected to a source terminal S of the fifth PMOS transistor 107. A drain terminal D of the fifth PMOS transistor 107 is connected to a drain terminal D of the sixth PMOS transistor 109. Gate terminals G of the fifth and the sixth PMOS transistors 107 and 109 are both connected to the drain terminal D of the NMOS transistor 101. A source terminal S of the sixth PMOS transistor 109 is connected to the PWM pin in the fan plug 11.

In some embodiments, such as the embodiment shown in FIG. 1, the computer fan 15 further includes a second tachometer terminal TACH2_FAN, and the computer fan module 13 further includes a seventh and an eighth PMOS transistor 115 and 117. The second tachometer terminal TACH2_FAN of the computer fan 15 is connected to a source terminal S of the seventh PMOS transistor 115. A drain terminal D of the seventh PMOS transistor 115 is connected to a drain terminal D of the eighth PMOS transistor 117. Gate terminals G of the seventh and the eighth PMOS transistors 115 and 117 are both connected to the drain terminal D of the NMOS transistor 101. A source terminal S of the eighth PMOS transistor 117 is connected to the second tachymeter pin TACH2 in the fan plug 11.

In operation, the first to the eighth PMOS transistors (103, 105, 111, 113, 107, 109, 115, and 117) are switched on by the NMOS transistor 101 after the delay. When the PMOS transistors are switched on, the terminals (P12V_FAN, TACH1_FAN, PWM_FAN, TACH2_FAN) of fan 15 are connected to the corresponding pins (P12V, TACH1, PWM, TACH2) in the fan plug 11.

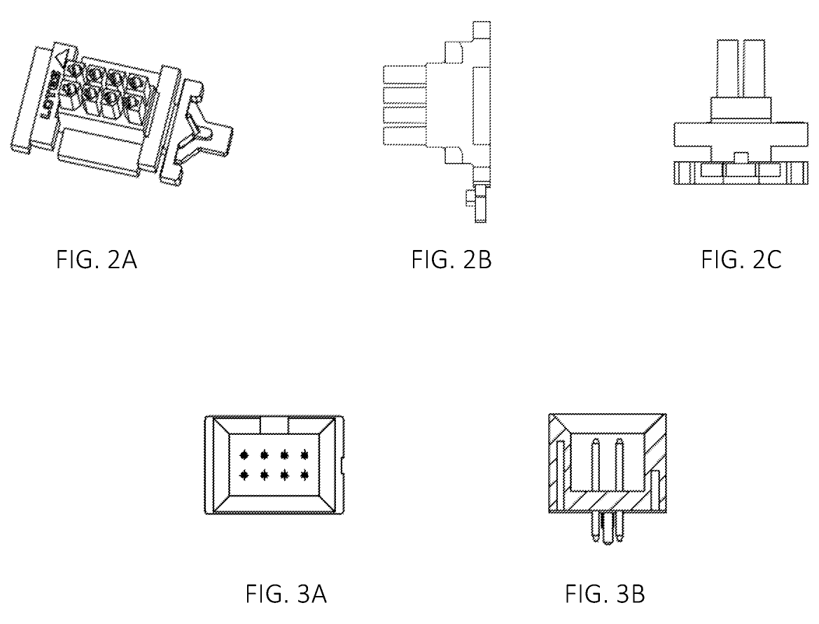

FIGS. 2A, 2B, and 3C illustrate a female fan connector. FIG. 2A presents a perspective drawing of the female fan connector, and FIGS. 2B and 2C present two lateral views of the female fan connector. FIGS. 3A and 3B illustrate a corresponding male fan connector that can mate with the female connector. In some embodiments, the fan plug of the fan is the female fan connector, and the fan connector of the motherboard is the male fan connector. In some embodiments, the fan plug of the fan is the male fan connector, and the fan connector of the motherboard is the female fan connector. In some embodiments, the 8-pin male and female connectors shown in FIGS. 2A–C and 3A–B can connect two computer fans to a computer system, where each computer fan requires a 4-pin connection. In some embodiments, the 4-pin connection for a computer fan includes pins for power, ground, PWM, and tachometer.

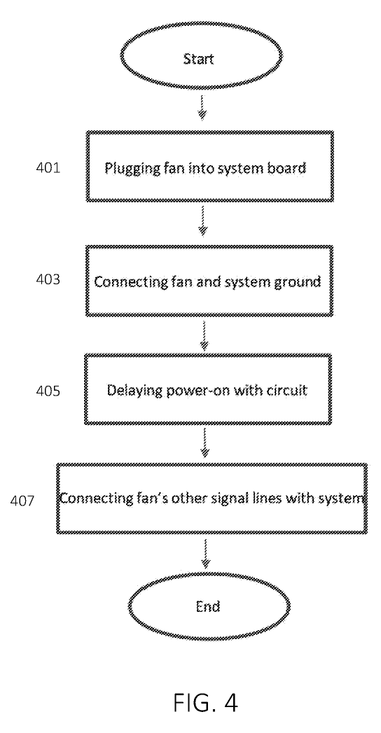

FIG. 4 illustrates the steps in a method of connecting a fan to a computer system. The method starts with step 401, in which a fan is plugged in a system board, which is the motherboard of a computer. Subsequently in step 403, the fan’s ground and the computer system’s ground are connected. In step 405, a circuit delays the power-on of fan for a predetermined duration of time. In step 407, after the delay of a predetermined duration of time, the signal and power lines of the fan is connected to the computer system.

In some embodiments, the delay of a predetermined duration of time is between about 10 milliseconds and about 50 milliseconds. In some embodiments, the delay is between about 15 and about 45 milliseconds, between about 20 and about 40 milliseconds, between about 25 and about 40 milliseconds, or between about 30 and about 35 milliseconds. In some embodiments, the delay is between about 15 and about 45 milliseconds, between about 20 and about 40 milliseconds, between about 25 and about 40 milliseconds, or between about 30 and about 35 milliseconds. In some embodiments, the delay is more than about 5 milliseconds, more than about 10 milliseconds, more than about 15 milliseconds, more than about 20 milliseconds, more than about 25 milliseconds, more than about 30 milliseconds, more than about 35 milliseconds, more than about 40 milliseconds, more than about 45 milliseconds, or more than about 50 milliseconds. In some embodiments, the delay is less than about 5 milliseconds, less than about 10 milliseconds, less than about 15 milliseconds, less than about 20 milliseconds, less than about 25 milliseconds, less than about 30 milliseconds, less than about 35 milliseconds, less than about 40 milliseconds, less than about 45 milliseconds, or less than about 50 milliseconds.

The circuitry, devices, system, and methods according to the present disclosure can avoid the “ground bounce” effect that may damage equipment and have several additional advantages. In particular, the circuitry disclosed herein can be integrated into the fan module without requiring any extra components on the computer motherboard, where space is restricted and precious. In addition, the computer fan can use any off-the-shelf connectors without restriction.

The foregoing description of the present disclosure has been provided for the purposes of illustration and description. It is not intended to be exhaustive or to limit the disclosure to the precise forms disclosed. The breadth and scope of the present disclosure should not be limited by any of the above-described exemplary embodiments. Many modifications and variations will be apparent to the practitioner skilled in the art. The modifications and variations include any relevant combination of the disclosed features. The embodiments were chosen and described in order to best explain the principles of the disclosure and its practical application, thereby enabling others skilled in the art to understand the disclosure for various embodiments and with various modifications that are suited to the particular use contemplated. It is intended that the scope of the disclosure be defined by the following claims and their equivalence.

What is claimed is:

1. A computer fan system comprising:
a computer fan comprising a ground terminal and a power terminal;
an N-type Metal-Oxide Semiconductor (NMOS) transistor comprising a source terminal connected to ground;
a first resistor connected between a positive voltage supply and a gate terminal of the NMOS transistor;
a second resistor connected between the gate terminal of the NMOS transistor and the ground;
a third resistor connected between the positive voltage supply and a drain terminal of the NMOS transistor;
a capacitor connected between the gate terminal of the NMOS transistor and the ground; and
a first and a second P-type Metal-Oxide Semiconductor (PMOS) transistor;
wherein the ground terminal of the computer fan is connected to the ground;
wherein the power terminal of the computer fan is connected to a source terminal of the first PMOS transistor;
wherein a drain terminal of the first PMOS transistor is connected to a drain terminal of the second PMOS transistor;
wherein gate terminals of the first and the second PMOS transistors are both connected to the drain terminal of the NMOS transistor; and
wherein a source terminal of the second PMOS transistor is connected to the positive voltage supply.

2. The computer fan system of claim 1, wherein the positive voltage supply is a +12V DC voltage supply.

3. The computer fan system of claim 1, wherein the computer fan further comprises a tachometer terminal; and wherein the computer fan system further comprises:
a third and a fourth PMOS transistor;
wherein the tachometer terminal of the computer fan is connected to a source terminal of the third PMOS transistor;
wherein a drain terminal of the third PMOS transistor is connected to a drain terminal of the fourth PMOS transistor; and
wherein gate terminals of the third and the fourth PMOS transistors are both connected to the drain terminal of the NMOS transistor.

4. The computer fan system of claim 3, wherein the computer fan further comprises a Pulse-Width Modulation (PWM) terminal; and wherein the computer fan system further comprises:
a fifth and a sixth PMOS transistor;
wherein the PWM terminal of the computer fan is connected to a source terminal of the fifth PMOS transistor;
wherein a drain terminal of the fifth PMOS transistor is connected to a drain terminal of the sixth PMOS transistor; and
wherein gate terminals of the fifth and the sixth PMOS transistors are both connected to the drain terminal of the NMOS transistor.

5. The computer fan system of claim 4, wherein the computer fan further comprises a second tachometer terminal; and wherein the computer fan system further comprises:
a seventh and an eighth PMOS transistor;
wherein the second tachometer terminal of the computer fan is connected to a source terminal of the seventh PMOS transistor;
wherein a drain terminal of the seventh PMOS transistor is connected to a drain terminal of the eighth PMOS transistor; and
wherein gate terminals of the seventh and the eighth PMOS transistors are both connected to the drain terminal of the NMOS transistor.

6. A computer system comprising the computer fan system of claim 1 and a motherboard; wherein the computer fan system is releasably attached to the motherboard via a fan plug and a fan connector; and wherein the computer fan system and the motherboard are connected via the ground and the positive voltage supply.

7. A computer system comprising the computer fan system of claim 3 and a motherboard; wherein the computer fan system is releasably attached to the motherboard via a fan plug and a fan connector; and wherein the computer fan system and the motherboard are connected via the ground, the positive voltage supply, and the drain terminal of the fourth PMOS transistor.

8. A computer system comprising the computer fan system of claim 4 and a motherboard; wherein the computer fan system is releasably attached to the motherboard via a fan plug and a fan connector; and wherein the computer fan system and the motherboard are connected via the ground, and the positive voltage supply, the drain terminal of the fourth PMOS transistor, and the drain terminal of the sixth PMOS transistor.

9. A computer system comprising the computer fan system of claim 5 and a motherboard; wherein the computer fan system is releasably attached to the motherboard via a fan plug and a fan connector; and wherein the computer fan system and the motherboard are connected via the ground, the positive voltage supply, the drain terminal of the fourth PMOS transistor, the drain terminal of the sixth PMOS transistor, and the drain terminal of the eighth PMOS transistor.

10. A device comprising:
a hardware component comprising a ground terminal and a first power or signal terminal;
an N-type Metal-Oxide Semiconductor (NMOS) transistor comprising a source terminal connected to a ground;
a first resistor connected between a positive voltage supply and a gate terminal of the NMOS transistor;
a second resistor connected between the gate terminal of the NMOS transistor and the ground;
a third resistor connected between the positive voltage supply and a drain terminal of the NMOS transistor;
a capacitor connected between the gate terminal of the NMOS transistor and the ground;
a first and a second P-type Metal-Oxide Semiconductor (PMOS) transistor;
wherein the ground terminal of the hardware component is connected to the ground;
wherein the first power or signal terminal of the hardware component is connected to a source terminal of the first PMOS transistor;
wherein drain terminals of the first and the second PMOS transistors are connected together; and
wherein gate terminals of the first and the second PMOS transistors are both connected to the drain terminal of the NMOS transistor.

11. The device of claim 10, wherein the hardware component is a hot-swappable computer hardware component.

12. The device of claim 10, wherein the hardware component is a computer fan.

13. A method of connecting a device to a computer system, comprising:
connecting a ground terminal of the device and an electrical ground of the computer system, and after a delay in time, connecting any signal or power terminal of the device to the computer system.

14. The method of claim 13, wherein the delay in time is between about 10 milliseconds and about 50 milliseconds.

15. The method of claim 13, wherein the device is a computer fan.

16. The method of claim 15, wherein connecting any signal or power terminal of the device to the computer system comprises:
connecting a power terminal, tachometer terminal, and a Pulse-Width Modulation (PWM) terminal of the fan to the computer system.

17. The method of claim 13, further comprising attaching a plug of the device to a corresponding connector of the computer system.

18. The method of claim 17, wherein the computer system is powered on when attaching the plug of the device to the corresponding connector of the computer system.

19. The method of claim 17, wherein the device is a computer fan, and the corresponding connector is a fan connector on a motherboard of the computer system.

20. The method of claim 13, wherein connecting any signal or power terminal of the device to the computer system after the delay in time comprises:
charging a capacitor until a voltage across the capacitor is sufficient to trigger an N-type Metal-Oxide Semiconductor (NMOS) transistor.
